(19) United States
(12) Patent Application Publication
(10) Pub. No.: US 2020/0278506 A1
(43) Pub. Date: Sep. 3, 2020

(54) Hybrid integration of photonic chips with single-sided coupling

(71) Applicant: Teknologian tutkimuskeskus VTT Oy, Espoo (FI)

(72) Inventors: Timo Aalto, Espoo (FI); Matteo Cherchi, Espoo (FI); Mikko Harjanne, Espoo (FI); Mircea Guina, Espoo (FI)

(21) Appl. No.: 16/645,496

(22) PCT Filed: Sep. 7, 2018
(86) PCT No.: PCT/FI2018/050635

§ 371 Date: Mar. 9, 2020

Related U.S. Application Data
(60) Provisional application No. 62/555,666, filed on Sep. 8, 2017.

(51) Int. Cl. G02B 6/42

(52) U.S. Cl. CPC G02B 6/423; H01S 5/4025

(57) ABSTRACT

According to an example aspect of the present invention, there is provided a method for integrating photonic circuits comprising optical waveguides, where a smaller chip with at least one first photonic circuit is aligned and bonded on top of a larger chip having at least one second photonic circuit in order to couple light between optical waveguides on each chip, wherein optical coupling between the waveguides on said chips occurs from a single side of said smaller chip.

### FIELD

The present invention relates to hybrid integration of photonic chips.

### BACKGROUND

Integrating a large number of optical or optoelectronic functions into a photonic integrated circuit (PIC) is possible by using either monolithic integration or hybrid integration. This disclosure mainly concerns hybrid integration which allows combining photonic functions from multiple waveguide chips into a single module or subassembly. In particular, the disclosure focuses on the flip-chip integration of one waveguide chip on top of another waveguide chip (or embedding one inside the other), so that they together form a hybrid PIC where light is coupled from the surrounding chip to the hybrid integrated (smaller) chip and then back to the surrounding chip.

### SUMMARY OF THE INVENTION

The invention is defined by the features of the independent claims. Some specific embodiments are defined in the dependent claims.

According to a first aspect of the present invention, there is provided a method for integrating photonic circuits comprising optical waveguides, where a smaller chip with at least one first photonic circuit is aligned and bonded on top of a larger chip having at least one second photonic circuit in order to couple light between optical waveguides on each chip, wherein optical coupling between the waveguides on said chips occurs from a single side of said smaller chip.

According to a second aspect of the present invention, there is provided a photonic integrated circuit comprising optical waveguides, said circuit having a smaller chip with at least one first photonic circuit and a larger chip having at least one second photonic circuit, wherein said smaller chip is aligned and bonded on top of said larger chip in order to couple light between optical waveguides on each chip, wherein optical coupling between the waveguides on said chips occurs from a single side of said smaller chip.

According to a third aspect of the present invention, there is provided a method for integrating photonic circuits comprising optical waveguides, where a smaller chip with at least one first photonic circuit is aligned and bonded on top of a larger chip having at least one second photonic circuit in order to couple light between optical waveguides on each chip, wherein optical coupling between the waveguides on said chips occurs from adjacent sides of said smaller chip.

### BRIEF DESCRIPTION OF THE DRAWINGS

In accordance with some embodiments of the invention described herein, photonic chips are hybrid integrated so that a smaller chip with U-shaped waveguides is aligned and bonded on the larger chip and light couples between the chips through a single facet. This allows the smaller chip to be first coarsely aligned and then fine-aligned using mechanical alignment. The invention can also be applied using other alignment methods. Single-sided coupling makes the chip alignment insensitive to small variations in the dimensions of the chip. In accordance with certain embodiments of the invention, the smaller chip may just have an array of bent waveguides. This type of arrangement of the waveguides is also considered as a photonic circuit in the context of this disclosure.

FIG. 1 illustrates, on the left, microscope image of a silicon-on-insulator (SOI) waveguide chip with flip-chip mounts for a semiconductor optical amplifier (SOA) chip and an electro absorption modulator (EAM) chip. Both the SOA and EAM chips contain an array of waveguides, interpreted in the context of this disclosure as a simple example of a PIC. On the right the mask layouts of the flip-chip mounts are shown.

FIG. 2 illustrates, on the left, an example cross-section of a flip-chip mount on 3 μm SOI waveguide chip and on the right a microscope image of an SOI chip with 3 EAM arrays flip-chip bonded on top.

FIG. 3 illustrates a schematic cross-section illustration of the larger and smaller chip.

FIG. 4 illustrates a schematic top-view illustration of the larger and smaller chip.

FIG. 5 illustrates a schematic top view of a coupling interface with tilted facets in both an SOI waveguide chip and an amplifier waveguide chip. Light is refracted in the material interfaces. On the right is illustrated the alignment challenge when the size of the small chip varies. With perfect alignment of the input waveguide the output interface can only be aligned perfectly if the chip size is perfect. A too large size prevents the chip from fitting into the flip-chip mount. A too small size causes a size-dependent lateral offset due to refraction of light in the gap between the waveguide facets.

FIG. 6 provides a schematic illustration of a fiber array that is coupled to the first waveguide chip (interposer), which is further coupled to another waveguide chip (3 μm SOI) where SOA and EAM chips are flip-chip integrated. Light makes a U-turn on the 3 μm SOI chip and returns back to the fiber array.

FIG. 7 provides an illustration of a novel SOA concept with ultra-small bends that allow all the I/O ports to be placed on a single chip facet (211) that is processed on wafer-scale to enable exact waveguide length control and passive mechanical alignment. The large chip (201) has a flip-chip mount (202) which comprises a plurality of mechanical alignment elements (212) which will facilitate the alignment with the alignment elements (210) on the smaller chip (203). This allows for accurate alignment of the waveguides (204, 205) between the chips.

FIG. 8 provides a schematic illustration of a mechanical alignment concept where the edge of the small chip (303) is not precisely controlled, but the waveguide alignment is still precise due to the use of longitudinally invariant alignment features. The longitudinal and transverse alignment features are separated. Small chip (303) is longitudinally pushed against the edge (308) of the flip-chip mount (302) while transverse alignment is obtained by pushing the alignment feature (307) on the small chip against a complementary feature (306) at the edge of the flip-chip mount (302).

FIG. 9 provides a schematic illustration of a mechanical alignment concept wherein tapered alignment feature (310) on the large chip (301) is providing mechanical alignment in both directions. When the small chip (303) is pushed longitudinally against the edge of the flip-chip mount (302) the tapered alignment feature (310) on the large chip and the rail-like alignment features (311) on the small chip make contact and align the two chips also in the transverse direction.

FIG. 10 shows a schematic top-view illustration of the benefits of the single-sided coupling and compact bends on the small chip. In this example the entire waveguide array is bent and not the individual waveguides.

### EMBODIMENTS

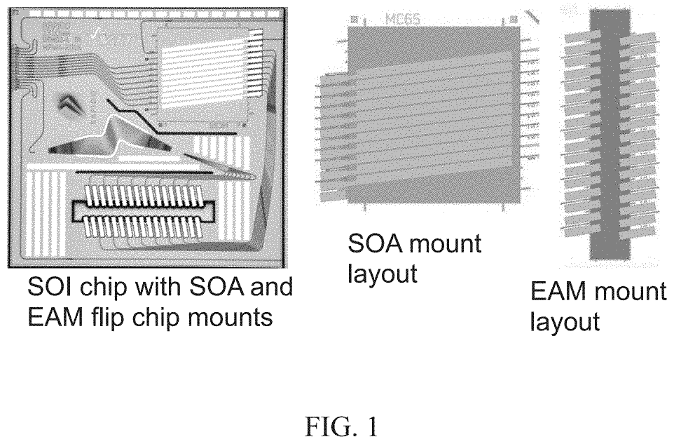

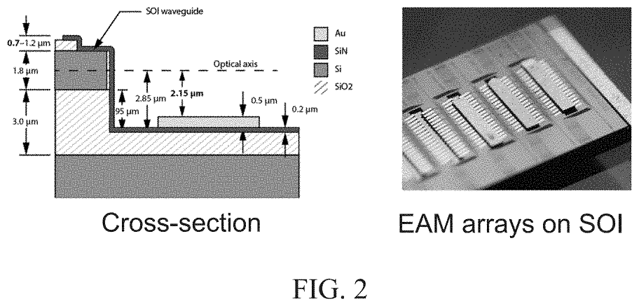

Integrating a large number of optical or optoelectronic functions into a photonic integrated circuit (PIC) is possible by using either monolithic integration or hybrid integration. This disclosure mainly concerns hybrid integration which allows combining photonic functions from multiple waveguide chips into a single module or subassembly. In particular, the disclosure focuses on the flip-chip integration of one waveguide chip on top of another waveguide chip (or embedding one inside the other), so that they together form a hybrid PIC where light is coupled from the surrounding chip to the hybrid integrated (smaller) chip and then back to the surrounding chip. Examples of the hybrid PIC can be seen in FIGS. 1 and 2.

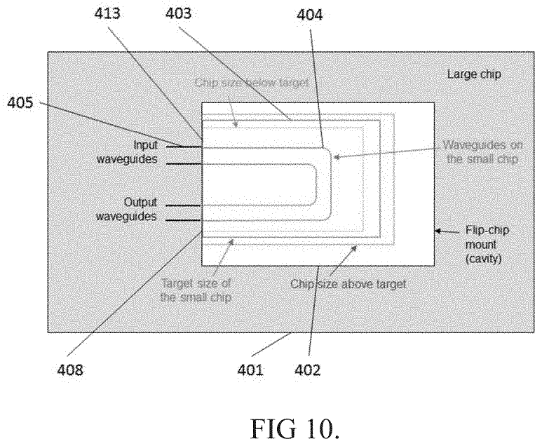

Both chips have optical waveguides that guide light. This invention is primarily intended for a case where the larger chip is a silicon photonic chip and the smaller chip is a compound semiconductor chip that provides amplification or modulation of light. However, the invention is not limited to these example cases and can be applied to many other types of waveguide chips, such as silica, silicon nitride or lithium niobate waveguide chips, which perform different optical functions, such as wavelength multiplexing/filtering, photodetection, lasing, sensing, imaging, wavelength conversion or optical logic. The smaller chip does not necessarily have to be flip-chip bonded on the larger chip, but it could also be otherwise embedded fully or partially inside the larger chip. For example, in certain embodiments in accordance with the invention, the smaller chip could also have the waveguide side up so that it is placed into a deep cavity that is formed into the larger chip (in a similar way as in the example in FIG. 10).

Coupling light between the two chips has many challenges. In each optical interface the alignment accuracy between the input and output waveguides depends on the used alignment method, bonding method, tools, and the alignment accuracy of the waveguide facets to any alignment marks or features that are used in the alignment. These alignment challenges are next discussed in detail.

Conventional flip-chip bonding is based on machine vision that is limited by the diffraction limit and the used optics and camera. Typical high-precision alignment accuracy with good optics is from ±0.2 to ±2 μm before the bonding.

However, the post-bond accuracy is typically worse since the chips are moved with respect to each other after the camera-based alignment. In a typical flip-chip configuration the camera is brought temporarily between the two chips for alignment and later the chips are brought into contact with an attempt to have a repeatable motion between alignment and bonding. Typical misalignment caused by such movement is from ±0.2 μm to ±2 μm (micrometers). In addition to this movement, the bonding process itself may also cause misalignment between the two chips, which is discussed later.

Alternatively, it is possible to use mechanical alignment wherein mechanical alignment features on the chips are pressed against each other. Self-alignment using solder reflow or evaporating fluid droplets has also been demonstrated. These approaches avoid the misalignment that is caused between the separate alignment and movement steps since the chips are in their targeted final positions after the alignment step. Sometimes different alignment methods can be simultaneously used in the different directions. For example, horizontal alignment can be based on machine vision while vertical alignment is based on the mechanical contact between the bonding pads.

Bonding can be done using adhesive, solder or thermo compression, for example. In adhesive bonding and soldering the surface tension of the fluidic bonding material can cause unwanted movements between the two chips. In adhesive bonding the curing of the adhesive can cause shrinking or expansion of the adhesive material, leading to unwanted movements. In thermo compression bonding the high mechanical force (or pressure) can move the chips or compress the bonding materials. In any high-temperature bonding process the temperature change before or after the bonding can cause different thermal expansion or shrinking for the two chips, which can cause misalignment between the waveguide facets. The bonding process itself typically causes ±0.2 to ±2 μm misalignment. The misalignments resulting from the alignment, chip movement and bonding process are typically not in the same direction, so that the overall misalignment from these three elements is typically from ±0.5 to ±4 μm and in the most precise methods the accuracy can be controlled within ±0.5 μm. It should also be noted that the amount of misalignment and the impact to the coupling efficiency can vary in the different alignment directions.

There is one more cause for misalignment: the finite alignment accuracy of the waveguide facets with respect to those features that are used in the alignment. In many cases this is dominating the final misalignment between the waveguide facets in the optical coupling interface, or in other words, the finite alignment accuracy of the waveguide facets has the most impact on misalignment. For example, if alignment marks are patterned as a separate processing step they might not be perfectly aligned with respect to the waveguide facets. In contact lithography a typical misalignment between mask layers is from ±1 to ±2 μm. Furthermore, the dicing or cleaving of chips from the original wafer or substrate can cause significant uncertainty in the dimensions of the chips and in the final positions of the chips. This also applies to the polishing of the chip edges that is sometimes used. Typical cleavage, dicing or polishing accuracy is from ±2 to ±20 μm.

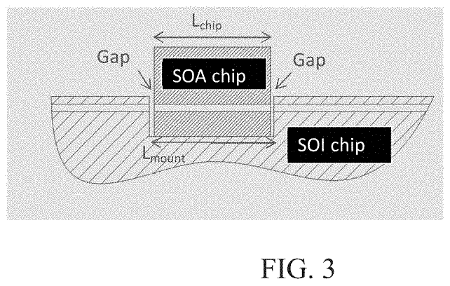

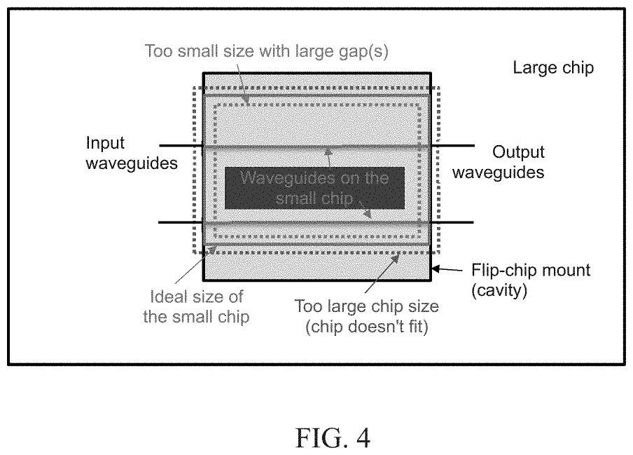

The focus of this disclosure is mainly on such applications where light is coupling from the larger chip to the smaller chip and then back to the larger chip. This is typically realized by coupling light in from one facet of the smaller chip and out from the opposite facet. Since the output and input waveguides have been readily processed on the larger chip the corresponding input and output facets on the smaller chip should be aligned to those. However, if the length of the smaller chip (L_{chip}) varies then the distance between the input and output facets on the smaller chip also varies and there will be a varying gap between the facets in each optical interface. If the smaller chip is too long it doesn't fit between the input and output facets on the larger chip where the waveguide facets are separated by the length of the flip-chip mount (Lₘₒᵤₙₜ). If it is too short there will be a large gap in at least one coupling interface and that causes significant optical coupling losses due to the divergence of the optical field in the gap, as seen in FIGS. 3 and 4.

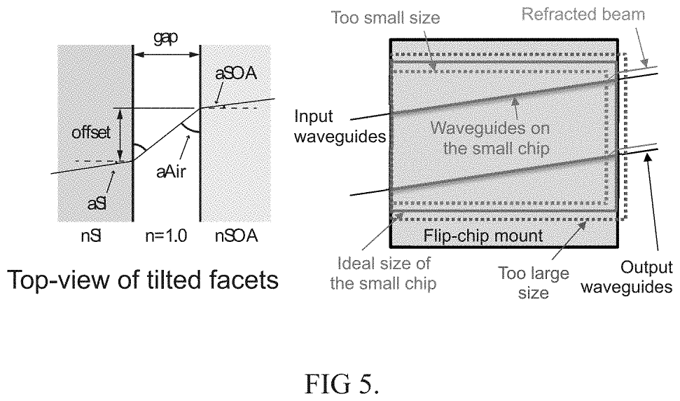

In some cases the waveguides are tilted with respect to the facet, for example to reduce back reflections in the facets. Due to light refraction the light will propagate in a different angle in the waveguide and in the gap between the facets (as shown in FIG. 5), so that the length variation of the smaller chip will make it impossible to perfectly align both the input and output facet in the horizontal direction.

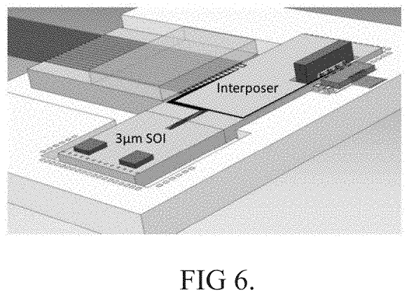

Coupling light in and out from the same facet avoids some of the problems associated with the finite control of the waveguide facet locations. This concept is widely used in the packaging of optical waveguide chips where a single fiber array is often aligned and attached to a single edge of an optical waveguide chip (as shown in FIG. 6Error! Reference source not found.). However, in the flip-chip integration of small chips on larger chips, the footprint of the small chips often limits the applicability of single-side coupling. The minimum bending radius of single mode waveguides is often in the same range or even larger than the size of the chip that is to be flip-chip integrated on the larger chip, so that no U-shaped waveguide bend fits into the chip. This is particularly true in the case where the small chip has a dense array of waveguides, such as parallel amplifiers (as shown in FIG. 1).

According to at least some embodiments of the present invention, light is coupled into the smaller chip and back to the larger chip from the same edge of the smaller chip. Optical waveguides (204) on the small chip are tightly bent using mirrors, Euler bends or other compact bends, so that even an array of waveguides can be coupled in and out from the same side of the smaller chip.

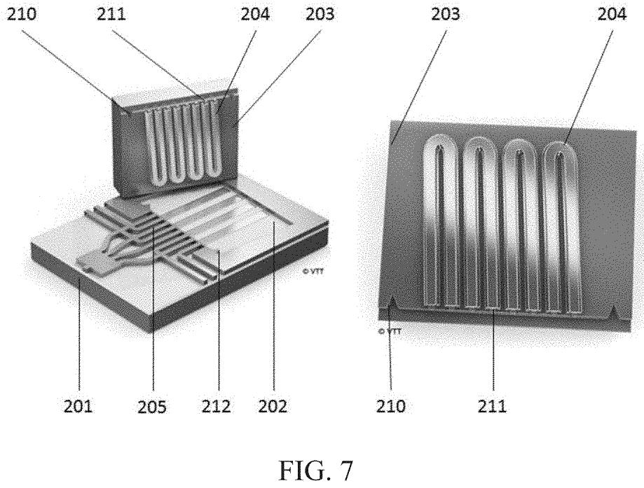

In a preferred embodiment of the invention the waveguide facets on both chips (201 and 203) are defined lithographically and the location of each waveguide facet is precisely aligned with respect to a mechanical alignment feature (212 and 210) on the edge of that chip (as shown in FIG. 7). Precise alignment between the waveguide (204) and the mechanical alignment feature (210) is preferably obtained by defining both features in the same lithographic mask layer, but also other methods can be used, such as precise alignment between mask layers using stepper lithography.

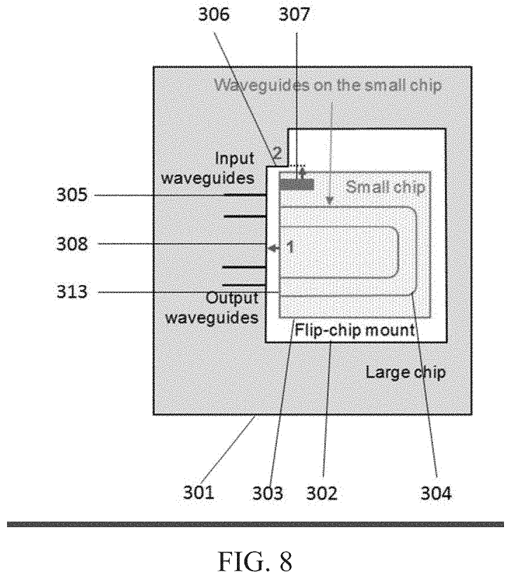

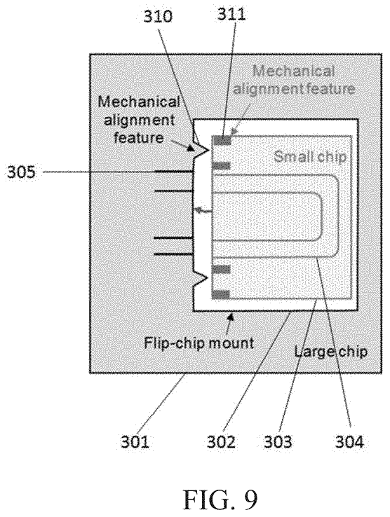

The mechanical alignment feature on the small chip can also be based on the combination of the chip edge (for longitudinal alignment) and longitudinal patterns that are invariant when the location of the chip edge is changed (as shown in FIGS. 8 and 9). In the first preferred embodiment the two chips are mechanically aligned with respect to each by moving the mechanical alignment features against each other. In certain embodiments, the edge of the small chip (303) is not precisely controlled, but the waveguide alignment is still precise due to the use of longitudinally invariant alignment features. The longitudinal and transverse alignment features are separated. Small chip (303) is longitudinally pushed against the edge (308) of the flip-chip mount (302) while transverse alignment is obtained by pushing the alignment feature (307) on the small chip against a complementary feature (306) at the edge of the flip-chip mount (302). Then also the waveguide facets are precisely aligned with respect to each other and therefore the waveguides (304, 305).

In accordance with certain embodiments of the invention, the longitudinal and transverse alignment features may be provided in a single feature (310), as can be seen in FIG. 9. The tapered alignment feature (310) on the large chip (301) is providing mechanical alignment in both directions. When the small chip (303) is pushed longitudinally against the edge of the flip-chip mount (302) the tapered alignment feature (310) on the large chip and the rail-like alignment features (311) on the small chip make contact and align the two chips also in the transverse direction.

One advantage of single-sided coupling is that the smaller chip can first be positioned further away from alignment features on the smaller chip by using coarse alignment. This is faster and easier to do than directly placing the small chip into a flip-chip mount that almost matches the size of the small chip (as shown in FIG. 3). When using mechanical alignment instead of camera-based alignment the advantage is that the misalignment caused by chip movement after the alignment is avoided or minimized. According to a second preferred embodiment of the invention, the edge (413) of the small chip (403) is not having any mechanical alignment features, except for the chip edge itself, and the alignment of the small chip is done based on using camera-based alignment, active alignment or solder-based self-alignment. Also in this case the single-sided input/output coupling is the key to avoid the alignment problems discussed above. The initial placement of the small chip into the flip-chip mount is easier and can be based on coarse alignment.

In accordance with some embodiments of the invention, the flip-chip mount (402) on the larger chip (401) is replaced with a deep cavity where the smaller chip is placed. In this “non-flipped” case the waveguides on both chips are facing up from the final assembly instead of in the smaller chip being up-side down. Also in this case the single-sided input/output coupling provides significant advantages. The smaller chip is easier to assemble into a deep cavity, which can be significantly larger than in the case of dual-sided coupling, as is illustrated in FIG. 10.

In accordance with some embodiments of the invention, the longitudinal alignment (along the waveguides) is based on mechanical alignment between the edge (413) of the smaller chip (403) and the edge of the large chip (408), while the transverse alignment is done using camera-based alignment, active alignment or solder-based self-alignment.

The variation in the length of the small chip does not automatically induce a varying gap between the waveguide facets as the chip edges can always be brought into close proximity or even into physical contact. When the input and output facets are on the same side of the small chip the relative positions of all the waveguide facets on the small chip can be kept unchanged even if the exact cleaving, etching or polishing line at the edge of the small chip varies (as shown in FIG. 10).

One benefit of the invention is that it allows a waveguide on the smaller chip to be even shorter than a waveguide that goes straight through the smaller chip. In this case the waveguide makes a very compact U-bend near the edge of the chip. With a sufficiently small bend the waveguide can be shorter than the minimum length of the chip, which is typically limited by the cleaving, dicing or handling of the chip. Such reduction of the waveguide length can be beneficial for very fast electro absorption modulators (EAMs), for example.

In accordance with some embodiments of the invention, the advantages described above are obtained by coupling light in and out through two adjacent facets instead of a single facet (as described above) or opposite facets (the conventional method in prior which is significantly larger than the small chip to ease the alignment process. The dimensions of the small chip can then vary and the small chip can be first coarsely positioned to the center of the mount and then moved to the corner of the mount using the same concepts have been described above in relation to single-sided coupling.

Additional benefits of the invention include more precise alignment and the ability to use chips that do not have precise size control. Mechanical alignment can be extremely precise, fast and inexpensive.

It is to be understood that the embodiments of the invention disclosed are not limited to the particular structures, process steps, or materials disclosed herein, but are extended to equivalents thereof as would be recognized by those ordinarily skilled in the relevant arts. It should also be understood that terminology employed herein is used for the purpose of describing particular embodiments only and is not intended to be limiting.

Reference throughout this specification to one embodiment or an embodiment means that a particular feature, structure, or characteristic described in connection with the embodiment is included in at least one embodiment of the present invention. Thus, appearances of the phrases “in one embodiment” or “in an embodiment” in various places throughout this specification are not necessarily all referring to the same embodiment. Where reference is made to a numerical value using a term such as, for example, about or substantially, the exact numerical value is also disclosed.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary. In addition, various embodiments and example of the present invention may be referred to herein along with alternatives for the various components thereof. It is understood that such embodiments, examples, and alternatives are not to be construed as de facto equivalents of one another, but are to be considered as separate and autonomous representations of the present invention.

Furthermore, the described features, structures, or characteristics may be combined in any suitable manner in one or more embodiments. In this description, numerous specific details are provided, such as examples of lengths, widths, shapes, etc., to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

While the forgoing examples are illustrative of the principles of the present invention in one or more particular applications, it will be apparent to those of ordinary skill in the art that numerous modifications in form, usage and details of implementation can be made without the exercise of inventive faculty, and without departing from the principles and concepts of the invention. Accordingly, it is not intended that the invention be limited, except as by the claims set forth below.

The verbs “to comprise” and “to include” are used in this document as open limitations that neither exclude nor require the existence of also un-recited features. The features recited in depending claims are mutually freely combinable unless otherwise explicitly stated. Furthermore, it is to be understood that the use of “a” or “an”, that is, a singular form, throughout this document does not exclude a plurality.

### INDUSTRIAL APPLICABILITY

At least some embodiments of the present invention find industrial application in hybrid integration of photonic chips.

### ACRONYMS LIST

EAM Electro-ab sorption modulator
LED Light emitting diode
PIC Photonic integrated circuit
SOA Semiconductor optical amplifier
SOI Silicon-on-insulator

REFERENCE SIGNS LIST

| | |
|---|---|
| 201 | Large chip |
| 202 | Flip-chip mount |
| 203 | Small chip |
| 204 | Waveguides |
| 205 | Waveguides |
| 210 | Mechanical alignment feature |
| 211 | Waveguide facet |
| 212 | Mechanical alignment feature |
| 301 | Large chip |
| 302 | Flip-chip mount |
| 303 | Small chip |
| 304 | Waveguides |
| 305 | Waveguides |
| 306 | Complementary feature at the edge of the flip-chip mount |
| 308 | Edge of flip-chip mount |
| 310 | Tapered alignment feature |
| 311 | Mechanical alignment feature on small chip |
| 401 | Large chip |
| 402 | Flip-chip mount |
| 403 | Small chip |
| 404 | Waveguides |
| 405 | Waveguides |
| 408 | Edge of flip-chip mount |
| 410 | Tapered alignment feature |
| 413 | Edge of the small chip |

1. A method for integrating photonic circuits comprising optical waveguides, where a smaller chip with at least one first photonic circuit is aligned and bonded on top of a larger chip having at least one second photonic circuit in order to couple light between optical waveguides on each chip, wherein light couples first from the larger chip to the smaller chip and then back to the larger chip from said smaller chip.

2. The method according to claim 1, wherein optical coupling between the waveguides is a single-sided coupling occurring from a single side of said smaller chip.

3. The method according to claim 1 wherein optical coupling between the waveguides on said chips occurs from adjacent sides of said smaller chip.

4. The method according to claim 1, wherein mechanical alignment features are formed on both said smaller and said larger chip to passively and precisely align the two chips and their respective waveguides together in at least one direction.

5. The method according to claim 4, wherein the mechanical alignment features support passive self-alignment in both the longitudinal direction and the transverse direction of said chips.

6. The method according to claim 5, wherein the longitudinal alignment is based on the mechanical contact between the edges of the chips where optical coupling occurs, and the transverse alignment is based on the mechanical contact between alignment features that are locally invariant in the longitudinal direction and insensitive to variations in the exact location of the chip edge and wherein at least one tapered feature on said larger chip mechanically interacts with alignment features on said smaller chip when the optically coupled edges of the two chips are moved towards each other, and that the alignment features on the smaller chip are locally invariant in the longitudinal direction, so that the alignment accuracy is not sensitive to variations in the exact location of the chip edge.

7. The method according to claim 1, wherein the optical waveguides on said smaller chip are bent using mirrors, Euler bends or other compact light turning elements with a bending radius of 1 mm or less.

8. The method according to claim 1, wherein the length of at least one waveguide on said smaller chip is shorter than the length of the smaller chip.

9. The method according to claim 1, wherein said at least one first photonic circuit of said smaller chip includes at least one array of the following dev ices or combinations of them: SOAs, EAMs, light emitting diodes (LEDs), lasers.

10.-25. (canceled)

26. A photonic integrated circuit comprising optical waveguides, said circuit having a smaller chip with at least one first photonic circuit and a larger chip having at least one second photonic circuit, wherein said smaller chip is aligned and bonded on top of said larger chip in order to couple light between optical waveguides on each chip, wherein light is coupled first from the larger chip to the smaller chip and the then back to the larger chip from said single side of said smaller chip.

27. A photonic integrated circuit according to claim 26, wherein optical coupling between the waveguides is a single-sided coupling occurring front a single side of said smaller chip.

28. A photonic integrated circuit according to claim 26, wherein optical coupling between the waveguides on said chips occurs from adjacent sides of said smaller chip.

29. A photonic integrated circuit according to claim 26, wherein mechanical alignment features are formed on both said smaller and said larger chip to passively and precisely align the two chips and their respective waveguides together in at least one direction.

30. A photonic integrated circuit according to claim 29, wherein the mechanical alignment features provide passive self-alignment in both the longitudinal direction and the transverse direction of said chips.

31. A photonic integrated circuit according to claim 30, wherein the mechanical contact between the edges of the chips where optical coupling occurs provide said longitudinal alignment, and the mechanical contact between alignment features that are locally invariant in the longitudinal direction and insensitive to variations in the exact location of the chip edge provide said transverse alignment.

32.-61. (canceled)

62. A photonic integrated circuit according to claim 26, wherein said smaller chip has a footprint of less than 2 cm2, and is aligned and bonded on top of said larger chip by means of flip-chip integration.

63. A photonic integrated circuit according to according to claim 26, wherein the waveguide facets on both chips are defined lithographically and the location of each waveguide facet is precisely aligned with respect to a mechanical alignment feature on the edge of that chip.

64. The method according to claim 1, wherein the waveguide facets on both chips are defined lithographically and the location of each waveguide facet is precisely aligned with respect to a mechanical alignment feature on the edge of that chip.

65. The method according to claim 1, wherein the waveguide and the mechanical alignment feature are defined in the same lithographic mask layer.
